(19) United States
(12) Patent Application Publication
(10) Pub. No.: US 2019/0300651 A1
(43) Pub. Date: Oct. 3, 2019

(54) COMPOSITION, ADHESIVE, SINTERED BODY, JOINED BODY, AND METHOD OF PRODUCING JOINED BODY

(71) Applicant: HITACHI CHEMICAL COMPANY, LTD., Tokyo (JP)

(72) Inventors: Masaki TAKEUCHI, Chiyoda-ku, Tokyo (JP); Fumitaka UENO, Chiyoda-ku, Tokyo (JP); Yoshitsugu MATSUURA, Chiyoda-ku, Tokyo (JP); Shinji AMANUMA, Chiyoda-ku, Tokyo (JP)

(21) Appl. No.: 16/467,821

(22) PCT Filed: Dec. 8, 2017
(86) PCT No.: PCT/JP2017/044253

§ 371 Date: Jun. 7, 2019

(30) Foreign Application Priority Data
Dec. 9, 2016 (JP) PCT/JP2016/086823

(51) Int. Cl. C08G 73/14; H01L 23/00; B22F 7/06; B22F 1/00; B22F 3/10

(52) U.S. Cl. CPC C08G 73/14; H01L 24/29; B22F 7/064; B22F 1/0059; B22F 3/1035; B22F 2301/30; H01L 2224/32225; H01L 2224/2929; H01L 2224/29347; H01L 2224/29311; B22F 2301/10; H01L 24/32

(57) ABSTRACT

A composition includes metal particles capable of transient liquid phase sintering and a thermoplastic resin having a softening point that is lower than the liquid phase transition temperature of the metal particles.

### TECHNICAL FIELD

The present invention relates to a composition, an adhesive, a sintered body, a joined body, and a method of producing a joined body.

### BACKGROUND ART

One example of a method of bonding a semiconductor element to a support member for manufacturing a semiconductor device is a method in which a solder powder is dispersed as a filler in a thermosetting resin such as epoxy resin to make a paste, and the paste is used as a conductive adhesive (see, for example, Patent Document 1).

In this method, after applying a paste-like conductive adhesive to a die pad of a support member by means of a dispenser, a printing machine, a stamping machine, or the like, a semiconductor element is die-bonded thereto, and the conductive adhesive is heat-cured, thereby manufacturing a semiconductor device.

In recent years, with the progress in speeding up and high integration of semiconductor elements, in order to operate semiconductor devices at high temperatures, bonding properties at low temperatures and connection reliability at high temperatures are required for conductive adhesives.

In order to improve the reliability of a solder paste in which a solder powder is dispersed as a filler, low-elasticity materials such as acrylic resins are being studied (see, for example, Patent Document 2).

In addition, an adhesive composition has been proposed, in which micro-sized or smaller silver particles subjected to a special surface treatment are sintered with each other by heating at from 100° C. to 400° C. (see, for example, Patent Documents 3 and 4). The adhesive composition, in which silver particles are sintered with each other, as proposed in Patent Documents 3 and 4 are considered to have excellent connection reliability at high temperatures because the silver particles form a metal bond.

Meanwhile, as an example of using metal particles other than silver particles, the development of transient liquid phase sintering-type metal adhesives is being promoted (see, for example, Patent Document 5, Non-Patent Document 1, and Non-Patent Document 2). For a transient liquid phase sintering-type metal adhesive, a combination of metal particles (for example, copper and tin) that generate a liquid phase at the joining interface is used as a metal component. An interfacial liquid phase is formed by heating when combining metal particles that generate a liquid phase at the joining interface. Thereafter, as the melting point of the liquid phase gradually rises due to the progress of reaction diffusion, the inching point of the composition of the joining layer eventually exceeds the joining temperature.

It is considered that connection reliability at high temperatures is improved by joining copper and a copper-tin alloy in the transient liquid phase sintering-type metal adhesives disclosed in Patent Document 5 and Non-Patent Documents 1 and 2.

### PRIOR ART REFERENCES

### Patent Documents

Patent Document 1: Japanese Patent Application Laid-Open (JP-A) No. 2005-93996

Patent Document 2: International Publication W02009/104693

Patent Document 3: Japanese Patent No. 4353380

Patent Document 4: Japanese Patent Application Laid-Open (JP-A) No. 2015-224263

Patent Document 5: Japanese National-Phase Publication (JP-A) No. 2015-530705

### NON-PATENT DOCUMENTS

Non-Patent Document 1: “Elemental technology and reliability of next-generation power semiconductor mounting (System Integration of Wide Band Gap Semiconductors)” (Jisedai power handotai jisso no yoso gijutsu to shinraisei) edited by Katsuaki Suganuma, CMC Publishing CO., LTD., May 31, 2016, pp. 29-30

Non-Patent Document 2: Lang Fengqun and three others, the 26th JIEP Annual Meeting Lecture Proceedings, the Japan institute of Electronics Packaging (JIEP), Jul. 17, 2014, pp. 295-296

### SUMMARY OF INVENTION

### Technical Problem

A resin component used for a transient liquid phase sintering-type metal adhesive is composed of a. thermosetting resin represented by an epoxy resin and additives such as flux, and has not been studied in detail.

According to the present inventors' investigation, a sintered body of a conventional transient liquid phase sintering-type metal adhesive including a thermosetting resin may have cracks generated in a cold-heat cycle (thermal shock) test.

One aspect of the invention has been made in consideration of the above-described conventional circumstances. An object of the invention is to provide: a composition that can form a sintered body via a transient liquid phase sintering method in which crack generation is suppressed in a cold-heat cycle test; an adhesive including the composition; and a sintered body, a joined body, and a method of producing a joined body using the composition.

### Solution to Problem

Specific means for achieving the above-described object are as follows.

<1> A composition, comprising:

metal particles capable of transient liquid phase sintering; and

a thermoplastic resin having a softening point that is lower than a liquid phase transition temperature of the metal particles.

<2> The composition according to <1>, wherein the metal particles comprise first metal particles containing Cu and second metal particles containing Sn.

<3> The composition according to <1> or <2>, wherein a mass ratio of the metal particles with respect to total solid content is 80% by mass or more.

<4> The composition according to any one of <1> to <3>, wherein the thermoplastic resin has a softening point that is at least 5° C. lower than the liquid phase transition temperature of the metal particles.

<5> The composition according to any one of <1> to <4>, wherein the thermoplastic resin has a softening point of 40° C. or more.

<6> The composition according to any one of <1> to <5>, wherein the thermoplastic resin has an elastic modulus of from 0.01 GPa to 1.0 GPa at 25° C.

<7> The composition according to any one of <1> to <6>, wherein the thermoplastic resin comprises at least one selected from the group consisting of an amide bond, an imide bond, and a urethane bond.

<8> The composition according to any one of <1> to <7>, wherein the thermoplastic resin comprises at least one selected from the group consisting of a poly amide resin, a polyamide imide resin, a polyimide resin, and a polyurethane resin.

<9> The composition according to any one of <1> to <8>, wherein the thermoplastic resin comprises at least one of a polyalkylene oxide structure or a polysiloxane structure.

<10> The composition according to <9>, wherein the polyalkylene oxide structure comprises a structure represented by the following Formula (1):

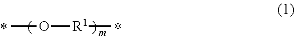

wherein, in Formula (1), R¹ represents an alkylene group, m represents an integer from 1 to 100. and * represents a bonding position with an adjacent atom. <11> The composition according to <10>, wherein the structure represented by Formula (1) comprises a structure represented by the following Formula (1A):

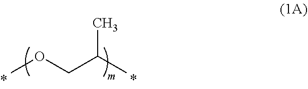

wherein, in Formula (1A), m represents an integer from 1 to 100 and * represents a bonding position with an adjacent atom.

<12> The composition according to any one of <9> to <11>, wherein the polysiloxane structure comprises a structure represented by the following Formula (2):

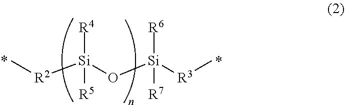

wherein, in Formula (2), each of R² and R³ independently represents a divalent organic group, each of R¹ to R⁷ independently represents an alkyl group having from 1 to 20 carbon atoms or an aryl group having from 6 to 18 carbon atoms, n represents an integer from 1 to 50, and * represents a bonding position with an adjacent atom.

<13> The composition according to any one of <1> to <6>, wherein:

the thermoplastic resin comprises a polyamide imide resin having a structural unit derived from a diimide carboxylic acid or a derivative thereof and a structural unit derived from an aromatic diisocyanate or an aromatic diamine,

a ratio of a structural unit represented by the following Formula (3) to the structural unit derived from a diimide carboxylic acid or a derivative thereof is 30 mol % or more, and a ratio of a structural unit represented by the following Formula (4) to the structural unit derived from a diimide carboxylic acid or a derivative thereof is 25 mol % or more:

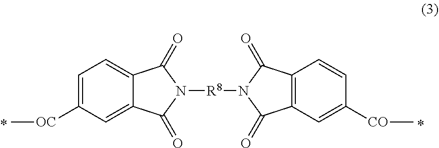

wherein, in Formula (3), R⁸ represents a divalent group having a structure represented by the following Formula (1), and * represents a bonding position with an adjacent atom:

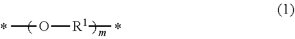

wherein, in Formula (1), R¹ represents an alkylene group, m represents an integer from 1 to 100, and * represents a bonding position with an adjacent atom, and:

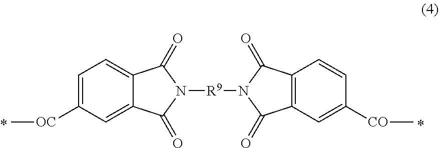

wherein, in Formula (4), R⁹ represents a divalent group having a structure represented by the following Formula (2), and * represents a bonding position with an adjacent atom:

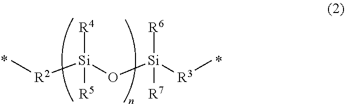

wherein, in Formula (2), each of R² and R³ independently represents a divalent organic group, each of R⁴ to R⁷ independently represents an alkyl group having from 1 to 20 carbon atoms or an aryl group having from 6 to 18 carbon atoms, n represents an integer from 1 to 50, and * represents a bonding position with an adjacent atom.

<14> An adhesive, comprising the composition according to any one of <1> to <13>.

<15> A sintered body, produced using the composition according to any one of <1> to <13>.

<16> A joined body, comprising an element and a support member that are joined via the sintered body according to <15>.

<17> A method of producing a joined body, the method comprising:

a step of providing the composition according to any one of <1> to <13> to at least one of a portion of a support member to which an element is to be joined, or a portion of the element to which the support member is to be joined, so as to form a composition layer;

a step of bringing the support member and the element into contact with each other via the composition layer; and

a step of sintering the composition layer by heating.

According to one aspect of the invention, it is possible to provide: a composition that can form a sintered body via a transient liquid phase sintering method in which crack generation is suppressed in a cold-heat cycle test; an adhesive including the composition; and a sintered body, a joined body and a method of producing a joined body using the composition.

### DESCRIPTION OF EMBODIMENTS

Embodiments of the invention are described below in detail. It is noted here, however, that the invention is not restricted to the below-described embodiments. In the below-described embodiments, the constituents thereof (including element steps and the like) are not indispensable unless otherwise specified. The same applies to the numerical values and ranges thereof, without restricting the invention.

In the present specification, those numerical ranges that are expressed with “to” each denote a range that includes the numerical values stated before and after “to” as the minimum value and the maximum value, respectively.

In a set of numerical ranges that are stated stepwisely in the present specification, the upper limit value or the lower limit value of a numerical range may be replaced with the upper limit value or the lower limit value of other numerical range. Further, in a numerical range stated in the present specification, the upper limit value or the lower limit value of the numerical range may be replaced with a relevant value indicated in any of Examples.

In the present specification, when there are plural kinds of substances that correspond to a component of a composition, the indicated content ratio of the component in the composition means, unless otherwise specified, the total content ratio of the plural kinds of substances existing in the composition.

In the present specification, when there are plural kinds of particles that correspond to a component of a composition, the indicated particle size of the component in the composition means, unless otherwise specified, a value determined for a mixture of the plural kinds of particles existing in the composition.

Herein, the term “laver” includes, when observing a region where a layer is present, a case in which the layer is formed only on a part of the region in addition to a case in which the layer is formed on the entirety of the region.

<Composition>

The composition of the disclosure contains metal particles capable of transient liquid phase sintering and a thermoplastic resin having a softening point that is lower than a liquid phase transition temperature of the metal particles.

The use of the composition of the disclosure makes it possible to form a sintered body via a transient liquid phase sintering method in which crack generation is suppressed in a cold-heat cycle test. Although the reason for that is unclear, it is presumed as follows.

In conventional adhesives (compositions) for which the transient liquid phase sintering method is used, an epoxy resin that is a thermosetting resin is widely used as a resin component. When a composition containing a thermosetting resin is heated, an alloy portion in which a metal component is sintered and a cured resin portion of a cured epoxy resin are formed in a sintered body of the composition. There is phase separation between the alloy portion and the cured resin portion in the sintered body of the composition, and the cured resin portion tends to be unevenly distributed in the sintered body. This is considered to be due to the fact that the alloy portion gradually grows as the sintering reaction of the metal component proceeds, and the epoxy resin is repelled from the portion where the metal particles or the alloy portion exists, In addition, as the sintering reaction of the metal component proceeds, the curing reaction of the epoxy resin which is a thermosetting resin also proceeds, it is considered that the alloy portion grows and the cured resin portion in the sintered body also grows easily.

When a cold-heat cycle test is performed on the sintered body in a state in which a cured resin portion is unevenly distributed, the strain caused by expansion and contraction of the cured resin portion tends to be concentrated at a part of the cured resin portion unevenly distributed in the sintered body. Further, since the thermosetting resin becomes hard to be deformed by curing, stress relaxation due to deformation of the cured resin portion cannot be expected as well. It is therefore thought that thermal stress is applied to the alloy portion at the location where the strain is concentrated, and crack generation occurs in the sintered body.

Meanwhile, for the composition of the disclosure, a thermoplastic resin having a softening point that is lower than a liquid phase transition temperature of metal particles is used as a resin composition. Since a thermoplastic resin does not cause a curing reaction by heating, no cured resin portion is generated in a sintered body. It is therefore thought that a thermoplastic resin is less likely to be unevenly distributed in a sintered body. Further, since a thermoplastic resin is easily deformed by heating, relaxation of stress due to the deformation of the thermoplastic resin can be expected. As a result of suppression of uneven distribution of a thermoplastic resin, a location where strain is concentrated in a sintered body is unlikely to exist. In view of the above, it is thought that thermal stress is less likely to be applied to an alloy portion, and crack generation is less likely to occur in a sintered body.

Hereinafter, each of the components that constitute the composition of the disclosure will be explained in detail.

(Metal Particles)

The composition of the disclosure includes metal particles capable of transient liquid phase sintering.

The term “transient liquid phase sintering” in the disclosure is also abbreviated as “MPS” and refers to a phenomenon that proceeds through transition to the liquid phase by heating at the particle interface of a low melting point metal and reaction diffusion of a high melting point metal to the liquid phase. Transient liquid phase sintering allows the melting point of a sintered body to exceed the heating temperature.

A combination of metals capable of transient liquid phase sintering which constitute metal particles capable of transient liquid phase sintering is not particularly limited. Examples of such a combination include, for example, a combination of Au and In, a combination of Cu and Sn, a combination of Sn and Ag, a combination of Sn and Co, and a combination of Sn and Ni.

In the disclosure, for metal particles capable of transient liquid phase sintering, as an example of a case in which a combination of metals capable of transient liquid phase sintering is a combination of Cu and Sn, a case in which first metal particles containing Cu and second metal particles containing Sn are used, a case in which metal particles each containing Cu and Sn are used and a case in which metal particles each containing Cu and Sn and first metal particles containing Cu or second metal particles containing Sn are used can be mentioned.

In a case in which first metal particles containing Cu and second metal particles containing Sn are used as the metal particles, the mass ratio of the first metal particles to the second metal particles (first metal particles/second metal particles) is preferably from 2.0 to 4.0, and more preferably from 2.2 to 3.5, although the ratio depends on the particle size of the metal particles.

Metal particles, each containing two kinds of metal, can be obtained by forming a layer containing one metal on the surface of a metal particle containing another metal, by plating, evaporation, or the like. In addition, metal particles each containing two kinds of metal can also be obtained by a method whereby particles containing the one metal are applied to the surfaces of metal particles containing the other of the metals, in a high-speed air stream using a force based on impact force in a dry system, thereby combining the respective particles.

In the disclosure, a combination of Cu and Sn is preferable as a combination of metals capable of transient liquid phase sintering.

In a case in which a combination of Cu and Sn is applied, Sn may be Sn alone or an alloy containing Sn, and is preferably an alloy containing Sn. Examples of an alloy containing Sn include Sn-3.0Ag-0.5Cu alloy. The notation for an alloy indicates that, for example, in the case of Sn-AX-BY, the tin alloy contains A% by mass of element X and B% by mass of element Y.

Since the reaction to form a copper-tin metal compound (Cu6Sn5) by sintering proceeds at around 250° C., sintering by a usual facility such as a reflow furnace is possible by using Cu and Sn in combination.

In the disclosure, the liquid phase transition temperature of metal particles refers to a temperature at which the transition of the metal particle interface to the liquid phase occurs.

For example, in a case in which particles of Sn-3.0 Ag-0.5 Cu alloy as a kind of tin alloy and copper particles are used, the liquid phase transition temperature is about 217° C.

The liquid phase transition temperature of metal particles can be measured by differential scanning calorimetry (DSC) using a platinum pan under conditions in which heating is performed from 25° C. to 300° C. at a heating rate of 10° C./ruin under a nitrogen stream of 50 ml/min.

The content of metal particles in the composition is not particularly limited. For example, a mass ratio of metal particles with respect to total solid content of the composition of the disclosure is preferably 80% by mass or more, more preferably 85% by mass or more, and still more preferably 88% by mass or more. In addition, the mass ratio of metal particles may be 98% by mass or less. When the mass ratio of metal particles is 98% by mass or less, the printability tends not to be impaired in a case in which the composition of the disclosure is used as a paste.

The average particle size of metal particles is not particularly limited. For example, the average particle size of the metal particles is preferably from 0.5 μm to 80 μm, more preferably from 1 μm to 50 μm, and still more preferably from 1 μm to 30 μm.

The average particle size of metal particles refers to a volume average particle size measured by a laser diffraction particle size distribution analyzer (for example, Beckman Coulter, Inc., LS 13 320-type laser scattering diffraction particle size distribution analyzer) Specifically, metal particles are added in a range of 0.01% by mass to 0.3% by mass to 125 g of a solvent (terpineol) to prepare a dispersion liquid, and about 100 ml of this dispersion liquid is injected to a cell for measurement at 25° C. Particle size distribution is measured by setting the refractive index of the solvent to 1.48.

(Thermoplastic Resin)

The composition of the disclosure contains a thermoplastic resin having a softening point that is lower than a liquid phase transition temperature of metal particles.

When the softening point of the thermoplastic resin is the same as or higher than the liquid phase transition temperature of the metal particles, melting and alloying of the metal particles occur before the thermoplastic resin softens when the composition of the disclosure is heated. Therefore, the thermoplastic resin that has not softened may inhibit the formation of liquid phase at the metal interface. Therefore, the softening point of the thermoplastic resin is set to a temperature lower than the liquid phase transition temperature of the metal particles.

The softening point of the thermoplastic resin is the value measured by thermomechanical analysis. The measurement conditions and the like will be described in detail in the section of “Examples.”

From the viewpoint of flowage without inhibiting alloy formation, the softening point of the thermoplastic resin is, preferably at least 5° C. lower, more preferably at least 10° C. lower, and still more preferably at least 15° C. lower than the liquid phase transition temperature of metal particles.

In addition, from the viewpoint of shape retention after printing when using the composition of the disclosure as a paste, the softening point of the thermoplastic resin is preferably 40° C. or more, more preferably 50° C. or more, and still more preferably 60° C. or more.

From the viewpoint of securing connection reliability, the elastic modulus of a thermoplastic resin at 25° C. is preferably from 0.01 GPa to 1.0 GPa, more preferably from 0.01 GPa to 0.5 GPa, and still more preferably from 0.01 GPa to 0,3 GPa.

The elastic modulus at 25° C. of the thermoplastic resin is the value measured by the method of JIS K 7161-1:2014.

From the viewpoint of dispersibility of a thermoplastic resin, it is preferable that the thermoplastic resin has a functional group or a structure that easily forms a hydrogen bond with the metal particle surface. Examples of a functional group that easily forms a hydrogen bond with the metal particle surface include an amino group and a carboxy group. In addition, examples of a structure that easily forms a hydrogen bond with the metal particle surface include an amide bond, an imide bond, and a urethane bond.

A thermoplastic resin preferably includes at least one selected from the group consisting of an amide bond, an imide bond, and a urethane bond.

Such a thermoplastic resin is at least one selected from the group consisting of a polyamide resin, a polyamide imide resin, a polyimide resin, and a polyurethane resin. A thermoplastic resin is preferably a polyatnide imide resin.

From the viewpoint of stress relaxation due to deformation of a thermoplastic resin, a thermoplastic resin preferably has a molecular structure exhibiting flexibility. The molecular structure exhibiting flexibility may be at least one of a polyalkylene oxide structure or a polysiloxane structure.

In a case in which a thermoplastic resin has a polyalkylene oxide structure, the polyalkylene oxide structure is not particularly limited. The polyalkylene oxide structure preferably includes, for example, a structure represented by the following Formula (1).

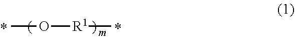

In Formula (1), R¹ represents an alkylene group, m represents an integer from 1 to 100, and * represents a bonding position with an adjacent atom. In a case in which the polyalkylene oxide structure is an aggregate of a plurality of structures, m represents a rational number that is the mean value.

In Formula (1), the alkylene group represented by IV is preferably an alkylene group having from 1 to 10 carbon atoms, and more preferably an alkylene group having from 1 to 4 carbon atoms. The alkylene group may be linear, branched, or cyclic. Examples of the alkylene group represented by R¹ include a methylene group, an ethylene group, a propylene group, a butylene group, a hexylene group, an octylene group, and a decylene group. Alkylene groups represented by R^{l} may be used singly, or in combination of two or more kinds thereof.

In Formula (1), m is preferably from 20 to 60, and more preferably from 30 to 40.

The structure represented by Formula (1) preferably includes a structure represented by the following Formula (1A).

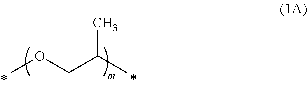

In Formula (1A), m represents an integer from 1 to 100 and * represents a bonding position with an adjacent atom. The preferred range of in is the same as in Formula (1).

In a case in which a thermoplastic resin has a polyalkylene oxide structure, a ratio of the polyalkylene oxide structure represented by Formula (1) to all polyalkylene oxide structures is preferably from 75% by mass to 100% by mass, more preferably from 85% by mass to 100% by mass, and still more preferably from 90% by mass to 100% by mass.

In a case in which a thermoplastic resin has the polyalkylene oxide structure represented by Formula (1), a ratio of the polyalkylene oxide structure represented by Formula (1A) to all polyalkylene oxide structures represented by Formula (1) is preferably from 50% by mass to 100% by mass, more preferably from 75% by mass to 100% by mass, and still more preferably from 90% by mass to 100% by mass.

In a case in which a thermoplastic resin has a polysiloxane structure, the polysiloxane structure is not particularly limited. The polysiloxane structure preferably includes, for example, a structure represented by the following Formula (2).

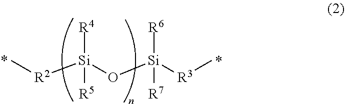

In Formula (2), each of R² and R³ independently represents a divalent organic group, each of R⁴ to R⁷ independently represents an alkyl group having from 1 to 20 carbon atoms or an aryl group having from 6 to 18 carbon atoms, n represents an integer from 1 to 50, and * represents a bonding position with an adjacent atom. In a case in which the polysiloxane structure is an aggregate of a plurality of structures, n represents a rational number that is the mean value.

In addition, the number of carbon atoms contained in a substituent is not included in the number of carbon atoms of the alkyl group or the aryl group.

In Formula (2), examples of divalent organic groups represented by R² and R³ include a divalent saturated hydrocarbon group, a divalent aliphatic ether group, and a divalent aliphatic ester group.

In a case in which each of R² and R³ represents a divalent saturated hydrocarb group, the divalent saturated hydrocarbon group may be linear, branched, or cyclic. In addition, the divalent saturated hydrocarbon group may have, as a substituent, a halogen atom such as a fluorine atom or a chlorine atom.

Examples of the divalent saturated hydrocarbon group represented by R² and that represented by R³ include a methylene group, an ethylene group, a propylene group, a butylene group, a pentylene group, a cyclopropylene group, a cyclobutylene group, and a cyclopentylene group. The divalent saturated hydrocarbon group represented by R² and that represented by R³ may be used singly, or in combination of two or more kinds thereof

Each of R² and R³ is preferably a propylene group.

In Formula (2), examples of alkyl groups having from 1 to 20 carbon atoms represented by R⁴ to R⁷ include a methyl group, an ethyl group, an n-propyl group, an isopropyl group, an n-butyl group, a t-butyl group, an n-octyl group, a 2-ethylhexyl group, and an n-dodecyl group. Of these, a methyl group is preferable.

In Formula (2), aryl groups having from 6 to 18 carbon atoms represented by R⁴ to R⁷ may be unsubstituted or substituted by a substituent. In a case in which an aryl group has a substituent, examples of the substituent include a halogen atom, an alkoxy group, and a hydroxy group.

Examples of the aryl group having from 6 to 18 carbon atoms include a phenyl group, a naphthyl group, and a benzyl group. Of these, a phenyl group is preferable.

Alkyl groups having from 1 to 20 carbon atoms or aryl groups having 6 to 18 carbon atoms represented by R⁴ to R⁷ may be used singly, or in combination of two or more kinds thereof.

In Formula (2), n is preferably from 5 to 25, and more preferably from 10 to 25.

A thermoplastic resin is preferably a polyamide imide resin which is a polymer having an amide bond and an imide bond in its main chain. A polyamide imide resin which has a structural unit derived from a diimide carboxylic acid or a derivative thereof and a structural unit derived from an aromatic diisocyanate or an aromatic diamine is preferable.

In a case in which a polyamide imide resin is a resin having a structural unit derived from a diimide carboxylic acid or a derivative thereof and a structural unit derived from an aromatic diisocyanate or an aromatic diamine, it is preferable that a ratio of a structural unit represented by the following Formula (3) to a structural unit derived from a diimide carboxylic acid or a derivative thereof is 30 mol % or more and a ratio of a structural unit represented by the following Formula (4) to a structural unit derived from a diimide carboxylic acid or a derivative thereof is 25 mol % or more, it is more preferable that a total proportion of a structural unit represented by the following Formula (3) and a structural unit represented by the following Formula (4) is 60 mol % or more, it is still more preferable that the total proportion of a structural unit represented by the following Formula (3) and a structural unit represented by the following Formula (4) is 70 mol % or more, and it is particularly preferable that the total proportion of a structural unit represented by the following Formula (3) and a structural unit represented by the following Formula (4) is 85 mol % or more.

The ratio of the structural unit represented by the following Formula (3) to the structural unit derived from a diimide carboxylic acid or a derivative thereof may be 60 mol % or less.

The ratio of the structural unit represented by the following Formula (4) to the structural unit derived from a diimide carboxylic acid or a derivative thereof may be 60 mol % or less.

The total proportion of the structural unit represented by the following Formula (3) and the structural unit represented by the following Formula (4) with respect to the structural unit derived from a diimide carboxylic acid or a derivative thereof may be 100 mol % or less.

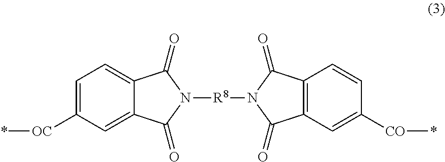

In Formula (3), R⁸ represents a divalent group having a structure represented by the following Formula (1), and * represents a bonding position with an adjacent atom.

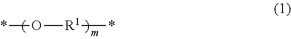

In Formula (1), R¹ represents an alkylene group, m represents an integer from 1 to 100, and * represents a bonding position with an adjacent atom. Specific examples of R¹, the preferable range of m, and the like are as mentioned above.

The structural unit represented by Formula (3) is preferably a structural unit represented by the following Formula (3A), and more preferably a structural unit represented by the following Formula (3B).

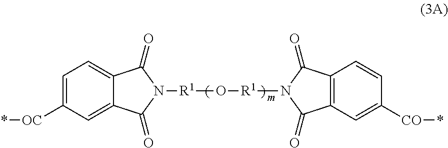

In Formula (3A), R¹ represents an alkylene group, m represents an integer from 1 to 100, and * represents a bonding position with an adjacent atom. Specific examples of the preferred range of m, and the like are the same as in Formula (1).

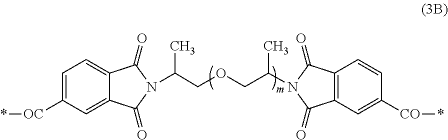

In Formula (3B), m represents an integer from 1 to 100 and * represents a bonding position with an adjacent atom. The preferred range of m and the like are the same as in Formula (1).

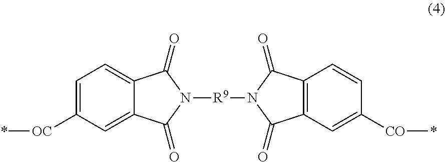

In Formula (4), R⁹ represents a divalent group having a structure represented by the following Formula (2), and * represents a bonding position with an adjacent atom.

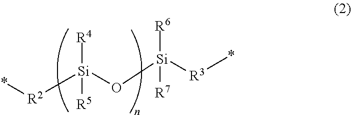

In Formula (2), each of R² and R³ independently represents a divalent organic group, each of R⁴ to R⁷ independently represents an alkyl group having from 1 to 20 carbon atoms or an aryl group having from 6 to 18 carbon atoms, n represents an integer from 1 to 50, and * represents a bonding position with an adjacent atom. Specific examples of R² to R⁷, the preferable range of n, and the like are as mentioned above.

The structural unit represented by Formula (4) is preferably a structural unit represented by the following Formula (4A).

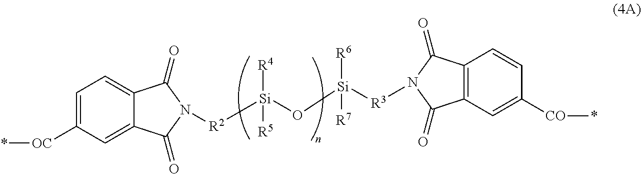

In Formula (4A), each of R² and R³ independently represents a divalent organic group, each of R⁴ to R⁷ independently represents an alkyl group having from 1 to 20 carbon atoms or an aryl group having from 6 to 18 carbon atoms, n represents an integer from 1 to 50, and * represents a bonding position with an adjacent atom. Specific examples of R² to R⁷, the preferred range of n, and the like are the same as in Formula (2).

The method of producing a polyamide imide resin is not particularly limited, and for example, the isocyanate method and the acid chloride method can be mentioned.

In the isocyanate method, a polyamide imide resin is synthesized using diimide carboxylic acid and aromatic diisocyanate. In the acid chloride method, a polyamide imide resin is synthesized using diimide carboxylic acid chloride and aromatic diamine. The isocyanate method involving synthesis from diimide carboxylic acid and aromatic diisocyanate is more preferable because it facilitates optimization of the polyamide imide resin structure.

Hereinafter, the method of synthesizing a polyamide imide resin by the isocyanate method will be explained in detail.

Diimide carboxylic acid used in the isocyanate method is synthesized using, for example, trimellitic anhydride and diamine. Preferred examples of diamine used in the synthesis of diimide carboxylic acid include siloxane-modified diamine, alicyclic diamine, and aliphatic diamine.

As siloxane-modified diamine, for example, one having the following structure formula can be mentioned.

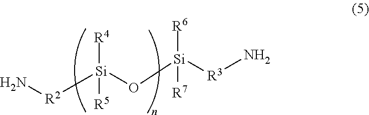

In Formula (5), each of R² and R³ independently represents a divalent organic group, each of R⁴ to R⁷ independently represents an alkyl group having from 1 to 20 carbon atoms or an aryl group having from 6 to 18 carbon atoms, and n represents an integer from 1 to 50. Specific examples of R² to R⁷, the preferred range of n, and the like are the same as in Formula (2).

Examples of commercially available siloxane-modified diamine include KF-8010, KF-8012, X-22-161A, X-22-161B, and X-22-9409 (manufactured by Shin-Etsu Chemical Co., Ltd.).

Examples of alicyclic diamine include 2,2-bis[4-(4-aminocyclohexyloxy)cyclohexyl]propane, bis[4-(3-aminocyclohexyloxy)cyclohexyl]sulfone, bis[4-(4-aminocyclohexyloxy)cyclohexyl]sulfone, 2,2-bis[4-(4-aminocyclohexyloxy)cyclohexyl]hexafluoropropane, bis[4-(4-aminocyclohexyloxy)cyclohexyl]methane, 4,4′-bis(4-aminocyclohexyloxy)dicyclohexyl, bis[4-(4-aminocyclohexyloxy)cyclohexyl]ether, bis[4-(4-aminocyclohexyloxy)cyclohexyl]ketone, 1,3-bis(4-aminocyclohexyloxy)benzene, 1,4- bis(4-aminocyclohexyloxy)benzene, 2,2′-dimethylbicyclohexyl-4,4′-diamine 2,2′-bis(trifluoromethyl)dicyclohexyl-4,4′-diamine, 2,6,2′,6′-tetramethyldicyclohexyl-4,4′-diamine, 5,5′-dimethyl-2,2′-sulfonyl-dicyclohexyl-4,4′-diamine, 3,3′-dihydroxydicyclohexyl-4,4′-diamine 4,4′-diaminodicyclohexyl ether, 4,4′-diaminodicyclohexyl sulfone, 4,4′-diaminodicyclohexyl ketone, 4,4′-diaminodicyclohexyl methane, 4,4′-diaminodicyclohexyl ether, 3,3′-diaminodicyclohexyl ether, and 2,2-bis(4-aminocyclohexyl)propane, which may be used singly, or in combination of two or more kinds thereof.

Of these, at least one cycloaliphatic diamine selected from the group consisting of 2,2-bis[4-(4-aminocylclohexyloxy)cyclohexyl]propane, bis[4-(3-aminocyclohexyloxy)cyclohexyl]sulfone, bis[4-(4-aminocyclohexyloxy)cyclohexyl]sulfone, 2,2-bis[4-(4-aminocyclohexyloxy)cyclohexyl]hexalluoropropane, bis[4-(4-aminocyclohexyloxy)cyclohexyl]methane, 4,4′-bis(4-aminocyclohexyloxy)dicyclohexyl, bis[4-(4-aminocyclohexyloxy)cyclohexyl]ether, bis[4-(4-aminocyclohexyloxy)cyclohexyl]ketone, and 4,4′-diaminodicyclohexylmethane is preferable.

As aliphatic diamine, oxypropylene diamine is preferable. Examples of commercially available oxypropylene diamine include JEFFAMINE D-230(manufactured by Mitsui Fine Chemicals, Inc., amine equivalent: 115, trade name), JEFFAMINE D-400(manufactured by Mitsui Fine Chemicals, Inc., amine equivalent: 200, trade name), JEFFAMINE D-2000 (manufactured by Mitsui Fine Chemicals, Inc., amine equivalent: 1,000, trade name), and JEFFAMINE D-4000(manufactured by Mitsui Fine Chemicals, Inc., amine equivalent: 2,000, trade name).

One of the above-described examples of diamine may be used singly, or they may be used in combination of two or more kinds thereof. A polyamide imide resin, which is synthesized using from 60 mol % to 100 mol % of the above-described diamine with respect to the total amount of diamine is preferable. In particular, in order to simultaneously achieve heat resistance and low elastic modulus, a siloxane modified polyimide imide resin, which is synthesized so as to include a siloxane modified diamine, is more preferable.

It is also possible to use aromatic diamine as diamine in combination, if necessary. Specific examples of aromatic diamine include p-phenylene diamine, m-phenylene diamine o-phenylene diamine, 2,4-diaminotoluene, 2.5-diaminotoluene., 2,4-diaminoxylene, diaminodurene, 1,5-diaminonaphthalene, 2,6-diaminonaphthalene, benzidine, 4,4′-diaminoterphenyl, 4,4′″-diaminoquaterphenyl, 4,4′-diaminodiphenylmethane, 1,2-bis(anilino)ethane, 4,4′-diaminodiphenyl ether, diaminodiphenylsulfone, 2,2-bis(p-aminophenyl)propane, 2,2-bis(p-aminophenyl)hexafluoropropane, 3,3′-dimethylbenzidine, 3,3′-dimethyl-4,4′-diaminodiphenyl ether, 3,3′-dimethyl-4,4′-diaminodiphenylinethane, diaminobenzotrifluoride, 1,4-bis(p-aminophenoxy)benzene, 4,4′-bis(p-aminophenoxy)biphenyl, 2,2′-bis {4-(p-aminophenoxy)phenyl}propane, diaminoanthraquinone, 4,4′-bis(3-aminophenoxyphenyl)diphenylsulfone, 1,3-bis(anilino)hexafluoropropane, 1,4-bis(anilino)octafluorobutane, 1,5-bis(anilino)decafluoropentane, 1,7-bis(anilino)tetradecafluoroheptane, 2,2-his {4-(p-aminophenoxy)phenyl}hexafluoropropane, 2,2-bis{4(3-aminophenoxy)phenyl}hexafluoropropane, 2,2-bis{4(2-aminophenoxy)phenyl}hexafluoropropane, 2,2-bis{4-(4-aminophenoxy)-3,5-dimethylphenyl}hexafluoropropane, 2,2-bis{4-(4-aminophenoxy)-3,5-ditrifluoromethylphenyl}hexafluoropropane, p-bis(4-amino-2-trifluoromethylphenoxy)benzene, 4,4′-bis(4-amino-2-trifluoromethylphenoxy)biphenyl, bis(4-amino-3-trifluoromethylphenoxy)biphenyl, 4,4′-bis(4-amino-2-trifluoromethylp enoxy)diphenylsulfone, 4,4′-bis(3-amino-5-trifluoromethylphenoxy)diphenylsulfone, 2,2-bis{4-(4-amino-3-trifluoromethylphenoxy)phenyl}hexafluoropropane, and 2,2-bis[4-(4-aminophenoxy)phenyl]propane. Aromatic diamine can be optionally used in a range of from 0 mol % to 40 mol % with respect to the total amount of diamine,

Examples of aromatic diisocyanate include diisocyanate obtained by the reaction of aromatic diamine with phosgene. Specific examples of aromatic diisocyanate include aromatic diisocyanates such as tolylene diisocyanate, 4,4′-diphenylmethane diisocyanate, naphthalene diisocyanate, diphenylether diisocyanate, and phenylene-1,3-diisocyanate. Of these, 4,4′-diphenylmethane diisocyanate, diphenylether diisocyanate, and the like are preferable.

A polymerization reaction of a polyamide imide resin by the isocyanate method is usually carried out in a solvent such as N-methyl-2-pyrrolidone (NMP), N,N-dimethyl formamide (DMF), N,N-dimethyl acetamide (DMAC), dimethyl sulfoxide (DMSO), dimethyl sulfate, sulfolane, γ-butyrolactone, cresol, halogenated phenol, cyclohexane, or dioxane. The reaction temperature is preferably from 0° C. to 200° C., more preferably from 100° C. to 180° C., and still more preferably from 130° C. to 160° C.

The molar ratio of diimide carboxylic acid to aromatic diisocyanate (diimide carboxylic acid/aromatic diisocyanate) in a polymerization reaction of a polyamide imide resin by the isocyanate method is preferably from 1.0 to 1.5, more preferably from 1.05 to 1.3, and still more preferably from 1.1 to 1.2.

(Solvent)

The composition of the disclosure may contain a solvent from the viewpoint of improving printability in a case in which the composition of the disclosure is used as a paste.

The solvent is preferably a polar solvent from the viewpoint of dissolving a thermoplastic resin. The solvent has preferably a boiling point of 200° C. or more from the viewpoint of preventing the composition from drying in the step of providing the composition, and more preferably a boiling point of 300° C. or less from the viewpoint of preventing void generation upon sintering.

Examples of such a solvent include: alcohols such as terpineol, stearyl alcohol, tripropylene glycol methyl ether, diethylene glycol, diethylene glycol monoethyl ether (ethoxy ethoxy ethanol), diethylene glycol monohexyl ether, diethylene glycol monomethyl ether, dipropylene glycol-n-propyl ether, dipropylene glycol-n-butyl ether, tripropylene glycol-n-butyl ether, 1,3-butanediol, 1,4-butanediol, and propylene glycol phenyl ether; esters such as tributyl citrate, 4-methyl-1,3-dioxolan-2-one, γ-butyrolactone, sulfolane, 2-(2-butoxyethoxy)ethanol, diethylene glycol monoethyl ether acetate, dipropylene glycol methyl ether acetate, diethylene glycol monobutyl ether acetate, and glycerin triacetate ketones such as isophorone; lactams such as N-methyl-2-pyrrolidone; nitriles such as phenylacetonitrile. Solvents may be used singly, or in combination of two or more kinds thereof.

In a case in which the composition of the disclosure contains a solvent, the content of the solvent is not particularly limited. The mass ratio of the solvent with respect to total amount of the composition of the disclosure is preferably from 0.1% by mass to 10% by mass, more preferably from 2% by mass to 7% by mass, and still more preferably from 3% by mass to 5% by mass.

(Additional Components)

The composition of the disclosure may contain additional components such as rosin, an activator, and a thixo agent, if necessary.

Examples of rosin that can be used for the composition of the disclosure include dehydroabietic acid, dihydroabietic acid, neoabietic acid, dihydropimaric acid, pimaric acid, isopimaric acid, tetrahydroabietic acid, and palustric acid.

Examples of an activator that can be used for the composition of the disclosure include amino decanoic acid, pentane-1.5-dicarboxylic acid, triethanolamine, diphenyl acetate, sebacic acid, phthalic acid, benzoic acid, dibromosalicylic acid, anisic acid, iodo salicylic acid, and picolinic acid.

Examples of a thixo agent that can be used for the composition of the disclosure include 12-hvdroxystearic acid, 12-hydroxystearic acid triglyceride, ethylene his stearic acid amide, hexamethylene his oleic acid amide, and N,N′-distearyl adipic acid amide.

A ratio of a thermoplastic resin in the solid content excluding metal particles in the composition of the disclosure is preferably from 5% by mass to 30% by mass, more preferably from 6% by mass to 28% by mass, and still more preferably from 8% by mass to 25% by mass. When the ratio of a thermoplastic resin in the solid content excluding metal particles is 5% by mass or more, the composition of the disclosure is likely to be in a paste state. When the ratio of a thermoplastic resin in the solid content excluding metal particles is 30% by mass or less, sintering of metal particles is less likely to be inhibited.

The composition of the disclosure may contain a thermosetting resin, if necessary. Examples of a thermosetting resin used according to the disclosure include, for example, an epoxy resin, an oxazine resin, a bismaleimide resin, a phenolic resin, an unsaturated polyester resin, and a silicone resin.

Specific examples of an epoxy resin include, for example, a hisphenol A type epoxy resin, a hisphenol F type epoxy resin, a hisphenol S type epoxy resin, a phenolic novolac type epoxy resin, a cresol novolac type epoxy resin, a naphthalene type epoxy resin, a biphenol type epoxy resin, a biphenyl novolac type epoxy resin, and a cycloaliphatic epoxy resin.

(Method of producing composition)

A method of producing the composition of the disclosure is not particularly limited. The composition of the disclosure can be obtained by mixing metal particles and a thermosetting resin which constitute the composition, and a solvent and additional components which are used if necessary and further performing treatments such as stirring, melting, and dispersion. A device for these treatments such as mixing stirring, and dispersion is not particularly limited, and a 3-roll mill, a planetary mixer, a sun-and-planet mixer, a planetary centrifugal mixer, a mortar machine, a biaxial kneader, a thin layer shear disperser, and the like can be used. In addition, these devices may be used in combination, if appropriate. Upon the above-described treatment, heating may be performed, if necessary.

After treatment, the maximum particle size of the composition may be adjusted by filtration. Filtration can be performed using a filtration device. Examples of a filter for filtration include, for example, metal mesh, metal filter, and nylon mesh.

<Adhesive>

The adhesive of the disclosure contains the composition of the disclosure. The composition of the disclosure may be directly used as the adhesive, and if necessary, it may contain additional components to be prepared as the adhesive. Preferred aspects of the adhesive of the disclosure are the same as in the case of the composition of the disclosure mentioned above.

<Sintered Body>

The sintered body of the disclosure is prepared by sintering the composition of the disclosure. A method of sintering the composition of the disclosure is not particularly limited.

The electrical resistivity of the sintered body is preferably 1×10⁻⁴ Ω·cm or less.

<Joined Body and Method of Producing Same>

The joined body of the disclosure is formed by joining an element and a support member via the sintered body of the disclosure.

The support member is not particularly limited, and one having a metal portion to be joined with an element is used. Examples of a metal forming the portion to be joined with an element include gold, silver, copper, and nickel. In addition, the support member may be formed by patterning a plurality of the above-described metals on a substrate.

Specific examples of the support member include a lead frame, a wired tape carrier, a rigid wiring board, a flexible wiring board, a wired glass substrate, a wired silicon wafer, and a rewiring layer employed for wafer level chip size package (CSP).

The element is not particularly limited, examples of which include active elements such as a semiconductor chip, a transistor, a diode, a light emitting diode, and a thyristor, and passive elements such as a capacitor, a resistor, a resistor array, a coil, and a switch.

In addition, examples of the joined body of the disclosure include a semiconductor device and an electronic component. Specific examples of a semiconductor device include a power module provided with a. diode, a. rectifier, a thyristor, a metal oxide semiconductor (MOS) gate driver, a power switch, a power metal oxide semiconductor field-effect transistor (MOSFET), an insulated gate bipolar transistor (IGBT), a Schottky diode or a fast recovery diode; a transmitter; an amplifier; and an LED module.

The method of producing a joined body of the disclosure includes a step of providing the composition of the disclosure to at least one of a portion of the support member to which the element is to be joined, or a portion of the element to which the support member is to be joined, so as to form a composition layer; a step of bringing the support member and the element into contact with each other via the composition layer; and a step of sintering the composition layer by heating.

The step of providing the composition so as to form a composition layer may include a step of drying the provided composition.

The composition layer is formed by providing the composition of the disclosure to at least one of a portion of the support member to which the element is to be joined and a portion of the element to which the support member is to be joined

Examples of a method of providing the composition include, for example, a coating method and a printing method.

Examples of a coating method of coating the composition that can be used include, for example, dipping, spray coating, bar coating, die coating, comma coating, slit coating, and applicator coating. Examples of a printing method of printing the composition that can be used include, for example, a dispenser method, a stencil printing method, an intaglio printing method, a screen printing method, a needle dispenser method, and a jet dispenser method

The composition layer formed by providing the composition is preferably dried from. the viewpoint of suppressing the flowage of the composition and the generation of voids during heating.

A method of drying the composition layer may involve drying by standing at ordinary temperature (for example, 25° C.), drying by heating, or drying under reduced pressure. For drying by heating or drying under reduced pressure, a hot plate, a warm air dryer, a warm air oven, a nitrogen dryer, an infrared dryer, an infrared heating oven, a far infrared heating oven, a microwave heating device, a laser heating device, an electromagnetic heating device, a heater heating device, a steam heating oven, a hot plate press device, or the like can be used.

The temperature and time for drying can be adjusted according to the type and amount of a solvent used, if appropriate. For example, drying is performed at preferably from 50° C. to 180° C. for 1 minute to 120 minutes.

After the formation of the composition layer, the element and the support member are brought into contact with each other so as to bond the element and the support member via the composition layer. The step of drying the provided composition may be carried out before or after the step of bringing the support member and the element into contact with each other.

Subsequently, the sintered body is formed by heating the composition layer. Sintering of the composition layer may he carried out by heating treatment or heating and pressurization treatment.

For heating treatment, a hot plate, a warm air dryer, a warm air oven, a nitrogen dryer, an infrared dryer, an infrared heating oven, a far infrared heating oven, a microwave heating device, a laser heating device, an electromagnetic heating device, a heater heating device, a steam heating oven, or the like can be used.

In addition, for heating and pressurization treatment, a hot plate press device or the like may be used, or the heating treatment may be carried out during pressurization.

The heating temperature for sintering the composition layer is preferably 180° C. or more, more preferably 190° C. or more, and still more preferably 220° C. or more, although it depends on the type of metal particles. The upper limit of the heating temperature is not particularly limited. However, the temperature is, for example, 300° C. or less.

The heating time for sintering the composition layer is preferably from 5 seconds to 10 hours, more preferably from 1 minute to 30 minutes, and still more preferably from 3 minutes to 10 minutes, although it depends on the type of metal particles.

In the method of producing a joined body of the disclosure, it is preferable to sinter the composition layer under an atmosphere at a low oxygen concentration. Under such an atmosphere at a low oxygen concentration, the oxygen concentration is 1000 ppm or less, and preferably 500 ppm or less.

### EXAMPLES

Hereinafter, the invention will he more specifically described by way of examples, but the invention is not limited to the following examples.

The measurement of each characteristic was carried out as follows in each of the Examples and Comparative example.

(1) Die Shear Strength

A composition prepared by the method described later was applied on a copper lead frame using pointed tweezers to form a composition layer. An Si chip having a size of 2 mm×2 mm and a gold-plated joining surface was placed on the composition layer and lightly pressed with the tweezers, thereby preparing a sample before sintering of the composition. The sample before sintering was dried on a hot plate at 100° C. for 30 minutes, and then, the sample was set on the conveyor of a nitrogen reflow system (manufactured by TAMURA Corporation: 50 cm per zone, 7-zone configuration, under a nitrogen stream) and transported at a speed of 0.3 m/min with an oxygen concentration of 200 ppm or less. At this time, the sample was heated at 250° C. or more for 1 minute or more and was used as a sintered composition sample. The adhesion strength of the sintered composition sample was evaluated by die shear strength.

Using an all-purpose bond tester (4000 series, manufactured by DAGE) equipped with a 1 kN load cell, the Si chip was pressed horizontally at a measurement speed of 500 μm/s and a measurement height of 100 μm, and the die shear strength of the sintered composition sample was measured. The average of nine measurements was designated as the die shear strength. Note that when the die shear strength is less than 20 MPa, it can be said that adhesion is poor.

(2) Cross-Sectional SEM Observation

A sintered composition sample was prepared in the same manner as in “(1) Die Shear Strength.” The sintered composition sample was fixed in a cup with a sample clip (SamplklipI, manufactured by Buehler), and an epoxy cast resin (EPOMOUNT, manufactured by Refine Tec Ltd.) was poured therearound until the whole sample was embedded, and the cup was left in a vacuum desiccator for defoaming by decompression for 30 seconds. Then, the cup was left at room temperature (25° C.) for 8 hours or more, thereby curing the epoxy cast resin. The resin was shaved to the joining portion with a polishing device (Refine Polisher HV, manufactured by Refine Tec Ltd.) to which water resistant abrasive paper (CARBOMAC PAPER, manufactured by Refine Tec Ltd.) was attached, thereby exposing the cutting cross-section. Thereafter, the cross-section was smoothed with a polishing device in which a buffing cloth impregnated with buffing compound was set. The cross-section of the sintered body of this sample for SEM was observed with an SEM device (TM-1000, manufactured by Hitachi, Ltd.) at an applied voltage of 15 kV.

(3) Measurement of Electrical Resistivity

A sintered composition sample was prepared in the same manner as in “(1) Die shear strength.” The resistivity was measured using a low resistance measurement device (3541 RESISTANCE HITESTER, manufactured by HIOKI E.E. Corporation) for the sintered composition sample. The distance between probes was 50 mm width.

(4) Thermal Shock Test (Cold-Heat Cycle Test)

A sintered composition sample was prepared in the same manner as in “(1) Die Shear Strength.” The sintered composition was set in a thermal shock tester (manufactured by Lifetech Inc., model 6015), and heated and cooled between 25° C. and 250° C. alternately in a repetitive manner at intervals of 30 seconds. After 20 cycles, 40 cycles, 60 cycles, 80 cycles, and 100 cycles, cross-sectional SEM observation of the sample was performed to confirm whether or not crack generation had occurred, and the number of cycles when crack generation occurred. In Table 1, “>100” means that no crack was generated even after 100 cycles. In Table 1, “<40” means that a crack was generated after 40 cycles.

(5) Resin Softening Point Test

A solution of the resin contained in each composition was applied to a mold-release-treated polyethylene terephthalate film (A31-75, manufactured by TEIJIN FILM SOLUTIONS LIMITED) using an applicator, and the solvent was removed by drying at 130° C. for 30 minutes, thereby preparing a resin film having a thickness of 100 μm. The obtained resin film was compressed at a force of 49 mN while heating at 10° C./min using a thermomechanical analyzer (TMA 8320, manufactured by Rigaku Corporation, measurement probe: standard type compression load method) so as to measure the softening point of the resin. The temperature shifted by 80 μm was designated as the softening point.

(6) Printability

A stainless steel metal mask (30 cm×30 cm, line width: 1.0 mm, line interval: 0.2 mm, 5 lines) was placed on a substrate and fixed to the substrate with adhesive tape so as to prevent the substrate from being displaced. The composition was collected in an amount of 20 g and uniformly applied to the top of the metal mask so as to fill grooves of the metal mask with the composition using a polypropylene squeegee. Thereafter, the metal mask was removed, thereby obtaining a printed matter. The above-described step was repeated 5 times without washing the metal mask. It was visually confirmed that the lines of each print matter were not connected and the corners of the lines were not collapsed. Thereafter, the printed matter was heated in the atmosphere at 200° C. for 1 minute, and it was confirmed that the lines were not connected. When the lines were not connected, it was evaluated as “OK.”

[Examples 1 to 4, Comparative Example 1]

(Synthesis of Thermoplastic Resin)

Synthesis Example 1—

To a 300-ml separable flask equipped with thermocouple, a stirrer, and a nitrogen inlet. 32.0 g of siloxane-modified diamine (X-22-16 IA, manufactured by Shin-Etsu Chemical Co., Ltd., trade name, diamine of Formula (5) in which R² and R³ are each an ethylene group (—CH₂CH₂—), R⁴ to R⁷ are all methyl groups, and n is about 20), 0.935 g of 4,4′-diaminodicyclohexylmethane (WANDAMIN HM (WHM), manufactured by New Japan Chemical Co., Ltd., trade name), 40.0 g of oxypropylene diamine (JEFFAMINE D-2000, manufactured by Mitsui Fine Chemicals, Inc., trade name, diamine for which the number of repetitions of (—OCH₂CH(CH₃)—) represented by in is about 33), 17.9 g of trimellitic anhydride, and 100 g of N-methyl-2-pyrrolidone were added, and stirred therein while flowing a nitrogen gas thereinto at about 250 ml/min for dissolution. Toluene in an amount of 50 g was added to this solution, and an imide ring closure reaction was carried out by dehydration reflux for 6 hours at a temperature of 150° C. or more. Then, after distilling off the toluene and cooling, 13.4 g of 4,4′-diphenylmethane diisocyanate (MDI) was added and reacted at 150° C. for 2 hours, thereby synthesizing polyamide imide resin 1. The solid content was 50% by mass.

Synthesis Example 2—

To a 300-ml separable flask equipped with thermocouple, a stirrer, and a nitrogen inlet, 15.0 g of siloxane-modified diamine (X-22-161A, manufactured by Shin-Etsu Chemical Co., Ltd., trade name), 5.73 g of 2,2-bis[4-(4-amino phenoxy)phenyl]propane (BAPP, manufactured by Wako Pure Chemical Industries, Ltd.), 23.6 g of oxypropylene diamine (JEFFAMINE D-2000, manufactured by Mitsui Fine Chemicals, Inc., trade name), 13.4 g of trimellitic anhydride, and 150 g of N-methyl-2-pyrrolidone were added, and stirred therein while flowing a nitrogen gas thereinto at about 250 ml/min for dissolution. Toluene in an amount of 50 g was added to this solution, and an imide ring closure reaction was carried out by dehydration reflux for 6 hours at a temperature of 150° C. or more. Then, after distilling off the toluene and cooling, 8.8 g of 4,4′-diphenylmethane diisocyanate (MDI) was added and reacted at 150° C. for 2 hours, thereby synthesizing polyamide imide resin 2. The solid content was 30% by mass.

(Preparation of Composition)

The polya.mid.e imide resin 1 in an amount of 0.82 g (1.64 g as a resin solution) and 0.31 g of 12-hydroxystearic acid (manufactured by Wako Pure Chemical Industries, Ltd.), 1.85 g of dehydroabietic acid (manufactured by Wako Pure Chemical Industries, Ltd.), 0.30 g of aminodecanoic acid (manufactured by Wako Pure Chemical Industries, Ltd.), and 4.10 g of ethoxyethoxyethanol (manufactured by Wako Pure Chemical Industries, Ltd.) were weighed and added to a 100-ml polyethylene bottle, the bottle was closed with an airtight stopper and stirred for 30 minutes with a rotor stirrer for mixing. To this mixture, 65.8 g of copper particles (manufactured by MITSUI MINING & SMELTING CO., LTD., spherical, average particle size: 10 μm) and 26.0 g of tin alloy particles (SAC305, Sn-3.0Ag-0.5Cu, manufactured by MITSUI MINING & SMELTING CO., LTD., spherical, average particle size: 3.0 μm) were weighed and added. The resulting mixture was stirred with a spatula until dry powder disappeared, and the bottle was closed with an airtight stopper and stirred with a planetary centrifugal mixer (Planetary Vacuum Mixer ARV-310, manufactured by THINKY CORPORATION) at 2000 rpm/min for 1 minute, thereby obtaining composition A.

Composition B was prepared using polyamide imide resin 2 (in an amount of 2.7 g as a resin solution) instead of the polyamide imide resin 1.

Composition C was prepared using epoxy resin (jER 828, manufactured by Mitsubishi Chemical Corporation) instead of the polyamide imide resin 1.

Composition D was prepared using a thermoplastic polyamide resin (Toray nylon fine particle SP-10, manufactured by Toray Industries, Inc.) instead of the polyamide imide resin 1.

Composition E was prepared using a freeze-ground thermoplastic polyurethane elastomer (Elastollan (registered trademark) C80A, manufactured by BASF SE) instead of the polyamide imide resin 1.

Each of the above-described characteristics were measured using the above-mentioned compositions. Table 1 shows the results. In Table 1, “−” means that the corresponding component was not contained.

In Table 1, hydroxystearic acid means 12-hydroxystearic acid. In Table 1, the column of Formula (3) in “Resin Structure” means the ratio of the structural unit represented by the following Formula (3) to the structural unit derived from diimide carboxylic acid, and the column of Formula (4) in “Resin Structure” means the ratio of the structural unit represented by the following Formula (4) to the structural unit derived from diimide carboxylic acid.

TABLE 1

| | | | | | Comparative | | |
|---|---|---|---|---|---|---|---|
| | | | Example 1 | Example 2 | Example 1 | Example 3 | Example 4 |
| Item | | Unit | Composition A | Composition B | Composition C | Composition D | Composition E |
| Resin | Resin Type | — | Polyamide imide | Polyamide imide | Epoxy resin | Polyamide resin | Polyurethane |
| Structure | | | resin 1 | resin 2 | | | resin |
| | Formula (3) | mol % | 45 | 34 | — | — | — |
| | Formula (4) | mol % | 45 | 27 | — | — | — |
| Composition | Copper particles | % by mass | 65.8 | 65.8 | 65.8 | 65.8 | 65.8 |
| | Tin alloy particles | % by mass | 26.0 | 26.0 | 26.0 | 26.0 | 26.0 |
| | Resin (solid content) | % by mass | 0.8 | 0.8 | 0.8 | 0.8 | 0.8 |
| | Resin (solvent content) | % by mass | 0.8 | 1.9 | — | — | — |
| | Hydroxystearic acid | % by mass | 0.3 | 0.3 | 0.3 | 0.3 | 0.3 |
| | Dehydroabietic acid | % by mass | 1.9 | 1.9 | 1.9 | 1.9 | 1.9 |
| | Amino decanoic acid | % by mass | 0.3 | 0.3 | 0.3 | 0.3 | 0.3 |
| | Ethoxy ethoxy ethanol | % by mass | 4.1 | 3.0 | 4.9 | 4.9 | 4.9 |
| Resin | Softening point | ° C. | 210 | 170 | Room | 165 | 140 |
| Property | | | | | temperature | | |
| | | | | | or less | | |
| Properties of | Printability | — | OK | OK | OK | OK | OK |
| Composition | Cross-section SEM | — | Sintering | Sintering | Sintering | Sintering | Sintering |
| and Sintering | observation | | | | | | |
| Body | Die shear strength | MPa | 36 | 37 | 35 | 32 | 34 |
| | Electric resistivity | Ω · cm | 3.9 × 10⁻⁷ | 4.1 × 10⁻⁷ | 3.7 × 10⁻⁷ | 4.0 × 10⁻⁸ | 4.2 × 10⁻⁹ |
| | Heat shock test | Number of | >100 | >100 | <40 | >100 | >100 |
| | | times | | | | | |

The printability of each of the compositions of the Examples and Comparative Example was favorable.

In Examples 1 to 4 and Comparative Example I in which the softening point of the resin was lower than the liquid phase transition temperature (217° C.) when tin alloy particles and copper particles were used, sintering proceeded, and the die shear strength after sintering and the volume resistivity were comparable. Meanwhile, it was confirmed that cracks were generated in the metal portion after 40 cycles in the thermal shock test in Comparative Example 1.

The disclosure of International Application No. PCT/JP2016/086823 filed on Dec. 9, 2016, is hereby incorporated by reference in its entirety.

All the documents, patent applications and technical standards that are described in the present specification are hereby incorporated by reference to the same extent as if each individual document, patent application or technical standard is concretely and individually described to be incorporated by reference.

1. A composition, comprising:
metal particles capable of transient liquid phase sintering; and
a thermoplastic resin having a softening point that is lower than a liquid phase transition temperature of the metal particles.

2. The composition according to claim 1, wherein the metal particles comprise first metal particles containing Cu and second metal particles containing Sn.

3. The composition according to claim 1, wherein a mass ratio of the metal particles with respect to total solid content is 80% by mass or more.

4. The composition according to claim 1, wherein the thermoplastic resin has a softening point that is at least 5° C. lower than the liquid phase transition temperature of the metal particles.

5. The composition according to claim 1, wherein the thermoplastic resin has a softening point of 40° C. or more.

6. The composition according to claim 1, wherein the thermoplastic resin has an elastic modulus of from 0.01 GPa to 1.0 GPa at 25° C.

7. The composition according to claim 1, wherein the thermoplastic resin comprises at least one selected from the group consisting of an amide bond, an imide bond, and a urethane bond.

8. The composition according to claim 1, wherein the thermoplastic resin comprises at least one selected from the group consisting of a polyamide resin, a polyamide imide resin, a polyimide resin, and a polyurethane resin.

9. The composition according to claim 1, wherein the thermoplastic resin comprises at least one of a polyalkylene oxide structure or a polysiloxane structure.

10. The composition according to claim 9, wherein the polyalkylene oxide structure comprises a structure represented by the following Formula (1): 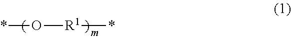
wherein, in Formula (1), R¹ represents an alkylene group, m represents an integer from 1 to 100, and * represents a bonding position with an adjacent atom.

11. The composition according to claim 10, wherein the structure represented by Formula (1) comprises a structure represented by the following Formula (1A): 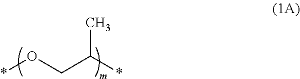
wherein, in Formula (1A), m represents an integer from 1 to 100 and * represents a bonding position with an adjacent atom.

12. The composition according to claim 9, wherein the polysiloxane structure comprises a structure represented by the following Formula (2): 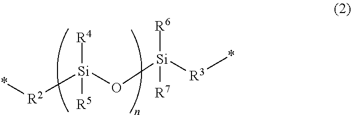
wherein, in Formula (2), each of R² and R³ independently represents a divalent organic group, each of R⁴ to R⁷ independently represents an alkyl group having from 1 to 20 carbon atoms or an aryl group having from 6 to 18 carbon atoms, n represents an integer from 1 to 50, and * represents a bonding position with an adjacent atom.

13. The composition according to claim 1, wherein:
the thermoplastic resin comprises a polyamide imide resin having a structural unit derived from a diimide carboxylic acid or a derivative thereof and a structural unit derived from an aromatic diisocyanate or an aromatic diamine,
a ratio of a structural unit represented by the following Formula (3) to the structural unit derived from a diimide carboxylic acid or a derivative thereof is 30 mol % or more, and
a ratio of a structural unit represented by the following Formula (4) to the structural unit derived from a diimide carboxylic acid or a derivative thereof is 25 mol % or more: 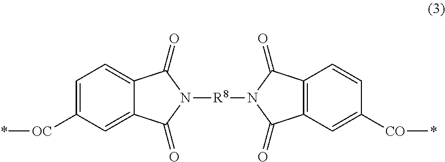
wherein, in Formula (3), R⁸ represents a divalent group having a structure represented by the following Formula (1), and * represents a bonding position with an adjacent atom: 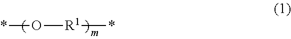
wherein, in Formula (1), R¹-represents an alkylene group, m represents an integer from 1 to 100, and * represents a bonding position with an adjacent atom, and: 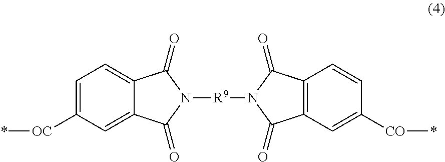
wherein, in Formula (4), R⁹ represents a divalent group having a structure represented by the following Formula (2), and * represents a bonding position with an adjacent atom: 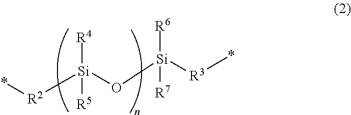
wherein, in Formula (2), each of R² and R³ independently represents a divalent organic group, each of R⁴ to R⁷ independently represents an alkyl group having from 1 to 20 carbon atoms or an aryl group having from 6 to 18 carbon atoms, n represents an integer from 1 to 50, and * represents a bonding position with an adjacent atom.

14. An adhesive, comprising the composition according to claim 1.

15. A sintered body, produced using the composition according to claim 1.

16. A joined body, comprising an element and a support member that are joined via the sintered body according to claim 15.

17. A method of producing a joined body, the method comprising:
providing the composition according to claim 1 to at least one of a portion of a support member to which an element is to be joined, or a portion of the element to which the support member is to be joined, so as to form a composition layer;
bringing the support member and the element into contact with each other via the composition layer; and
sintering the composition layer by heating.
